(19) United States
(12) Patent Application Publication
(10) Pub. No.: US 2015/0103505 A1
(43) Pub. Date: Apr. 16, 2015

(54) APPARATUS FOR MAKING CONTACT WITH A DIRECTION-DEPENDENT ELECTRICAL AND/OR ELECTRONIC COMPONENT, AND CORRESPONDING COMPONENT ARRANGEMENT

(71) Applicant: Christian Erbe, Stuttgart (DE)

(72) Inventor: Christian Erbe, Stuttgart (DE)

(73) Assignee: ROBERT BOSCH GMBH, Stuttgart (DE)

(21) Appl. No.: 14/356,856

(22) PCT Filed: Oct. 1, 2012
(86) PCT No.: PCT/EP2012/069345

§ 371 Date: May 7, 2014

(30) Foreign Application Priority Data
Nov. 7, 2011 (DE) 10 2011 085 832.6

(51) Int. Cl. H05K 5/00; H05K 1/11; H05K 1/18

(52) U.S. Cl. CPC H05K 5/0078; H05K 1/181; H05K 1/111; H05K 5/0069
USPC 361/767; 174/541

(57) ABSTRACT

A device is described for contacting a direction-dependent electrical and/or electronic component that includes a predetermined first number of functions to be contacted, having a basic body and having a predetermined first number of first contact elements that are respectively assigned, according to a predetermined connection assignment, to a function to be contacted, and are situated on the basic body with a predetermined positioning, as well as an associated component system having such a contacting device. The positioning of the first contact elements on the basic body is made rotationally symmetrical about an angle of 90°, so that when there is a rotation of the direction-dependent electrical and/or electronic component by 90°, no different component-based functions lie against one another.

### FIELD OF THE INVENTION

The present invention relates to a device for contacting a direction-dependent electrical and/or electronic component, and to a corresponding component system having such a contacting device.

### BACKGROUND INFORMATION

Currently, a housing for a component, including connection assignment (pinning), is selected taking into account size (costs), short bonding lengths, and testability. In order to create layouts that are to be used by a maximum number of clients having differing requirements, nowadays a very large number of assembly positions must be kept available on the circuit board. However, this quickly runs up against limits due to the limited available surface. In addition, there are further component-specific requirements. For sensors, vibrations/resonances play a large role, and these additionally change as a function of the location of installation or screw-on points, both of an electronic control unit (ECU) and of the circuit board and the desired direction of detection.

In German Published Patent Appln. No. 10 2009 042 653, for example, a method is described for the automatic assembly of substrates and components in assembly devices, the components and/or individual circuits that are to be assembled being predetermined by an assembly program. However, for the assembly of a substrate there may exist a plurality of possible assembly variants. For this reason, each substrate that is to be assembled is provided with an individual identifier. In addition, a list of the possible assembly variants and configurations is stored for a circuit board description. In the assembly device, the individual assembly variant and configuration for the respective substrate is then determined on the basis of this individual substrate identifier, and is specified to the assembly program of the assembly device. Standardly, the assembly program defines a sequence for carrying out the assembly of the substrate, starting from a description for the respective assembly, the so-called circuit board description, including for example a configuration of the substrate to be assembled, descriptions of the components used, etc.

### SUMMARY

In contrast, a device according to the present invention for contacting a direction-dependent electrical and/or electronic components, and the corresponding component system, has the advantage that through the use of a connection assignment (pinning) that is rotationally symmetrical about 90°, in the case of direction-dependent components, the flexibility and the degree of freedom can be massively increased in which the components or the electronic control unit (ECU) can be used. In addition, layout surface can be saved, or an optimized position can be used more simply. In connection with the present invention, pinning is to be understood as the assignment of component-based functions to the first connecting elements of the component.

Specific embodiments of the present invention make it possible for a client to use a standard layout for a plurality of cases of application having different directions of detection, so that for example a rotational rate sensor can also be used for a rollover functionality. Because control device plug connectors may be oriented in different directions for different clients, in the standard layout a second assembly place must be kept available for the direction-dependent electrical and/or electronic component. These places kept available multiply in number when one takes into account that the clients additionally use different screw-on positions for a corresponding electronic control unit (ECU), with the result that the direction-dependent electrical and/or electronic component must be situated at the right or at the left on the circuit board. Of the four installation positions, in the case of a direction-dependent electrical and/or electronic component having a contacting device rotatable by 90°, it is already possible to save two available places.

Specific embodiments of the present invention provide a device for contacting a direction-dependent electrical and/or electronic component that includes a predetermined first number of functions that are to be contacted, the device including a basic body and a predetermined first number of first contact elements that are each assigned to a function that is to be contacted in accordance with a predetermined connection assignment, and that are situated on the basic body with a predetermined positioning. According to the present invention, the positioning of the first contact elements on the basic body is made to be rotationally symmetrical about an angle of 90°, so that when there is a rotation of the direction-dependent electrical and/or electronic component by 90°, no different component-based functions will lie against one another.

Specific embodiments of a component system according to the present invention include a direction-dependent electrical and/or electronic component that includes a predetermined first number of functions that are to be contacted, and a component bearer that has a predetermined layout having a predetermined second number of second contact elements. The direction-dependent electrical and/or electronic component includes a contacting device according to the present invention having a basic body and a plurality of first contact elements that are respectively assigned to a function that is to be contacted according to a predetermined connection assignment, and are situated on the basic body with a predetermined positioning. According to the present invention, the positioning of the first contact elements on the basic body is made rotationally symmetrical about an angle of 90°, so that when there is a rotation of the direction-dependent electrical and/or electronic component by 90°, no different component-based functions lie against one another.

Exemplary embodiments of the present invention can be used in all areas in which the orientation of components plays a role, as is the case for example for direction-sensitive sensors such as rotational rate sensors and/or acceleration sensors. The possible uses of such components multiply given the use of a rotationally symmetrical pinning. The component bearer can for example be realized as a circuit board or substrate.

It is particularly advantageous that the basic body can be realized as a part of the component housing or as a component base. This enables a simple implementation of the present invention. As a function of the component housing or of the installation situation, the basic body can for example be made circular or rectangular, and the number of first contact elements can correspond to the first number of functions to be contacted.

In the realization of the contacting device as a component base into which the component is plugged, the connection assignment, or assignment of the first contact elements to the functions of the component that are to be contacted, can advantageously be adapted in such a way that the corresponding direction-dependent electrical and/or electronic component can be placed onto the component bearer both in a 0° orientation and in a 90° orientation. In this way, it is advantageously possible to correspondingly adapt conventional sensor types known from the existing art in order to make it possible to achieve the rotational symmetry.

In an advantageous embodiment of the component system according to the present invention, the second number of second contact elements is selected to be at least twice as large as the first number of first contact elements, a first contact element being capable of being connected to two second contact elements in each case.

In a further advantageous embodiment of the component system according to the present invention, the first contact elements are realized as connecting pins and the second contact elements are realized as pin receptacles.

In a further advantageous embodiment of the component system according to the present invention, the second contact elements are situated on the component bearer in such a way that the direction-dependent electrical and/or electronic component, in a first position having a first detection direction or in a second position having a second detection direction, can be contacted to the component bearer, the second detection direction having an angle of 90° to the first detection direction.

In a further advantageous embodiment of the component system according to the present invention, a first contact element of the direction-dependent electrical and/or electronic component is realized as an orientation element that, in the first position, is contacted to a second contact element that is connected to a first electrical potential, and in the second position is connected to a different second contact element that is connected to a second electrical potential, the current orientation of the direction-dependent electrical and/or electronic component, and thus the current direction of detection, being capable of being determined by querying the electrical potential present at the orientation element. This advantageously enables a simple automatic recognition of an unintentional misassembly, i.e. installation of the direction-dependent electrical and/or electronic component with the wrong orientation. Thus, the one second contact element can for example be connected to ground potential and the other second contact element can for example be connected to a supply voltage potential. If, now, the direction-dependent electrical and/or electronic component is assembled in the first direction of detection, then the corresponding first connecting element is connected to the ground potential. If the direction-dependent electrical and/or electronic component is assembled rotated by 90°, then the corresponding first connecting element is connected to the supply voltage potential. Thus, the direction-dependent electrical and/or electronic component can either itself recognize in which direction it has been installed, or the information can be handed over, via a further connecting element, to an evaluation and control unit that correspondingly processes the information. Alternatively, the orientation of the direction-dependent electrical and/or electronic component can take place by automatic optical inspection (AOI), via an imprint made on the direction-dependent electrical and/or electronic component.

The pinning of the corresponding contacting device, or of the direction-dependent electrical and/or electronic component, can be adapted, through specific embodiments of the present invention, in such a way that the direction-dependent electrical and/or electronic component can be assembled on the component bearer both in a 0° orientation and in a 90° orientation. The pinning of the corresponding contacting device fulfills the conditions of rotational symmetry if, when there is a rotation by 90°, no two different component-based functions lie against one another.

An exemplary embodiment of the present invention is shown in the drawings and is explained in more detail in the following description. In the drawings, identical reference characters designate components or elements that execute identical or analogous functions.

### BRIEF DESCRIPTION OF THE DRAWINGS

FIG. 1 shows a schematic sectional representation of an exemplary embodiment of a component system according to the present invention.

FIG. 2 shows a schematic top view of an exemplary embodiment of a contacting device according to the present invention in a first direction of detection (X) for the component system of FIG. 1.

FIG. 3 shows a schematic top view of the exemplary embodiment of a contacting device according to the present invention of FIG. 2, in a second direction of detection (Y).

FIG. 4 shows a schematic top view of an exemplary embodiment of a component bearer for accommodating the contacting device according to the present invention, according to FIGS. 2 and 3 for the component system of FIG. 1.

### DETAILED DESCRIPTION

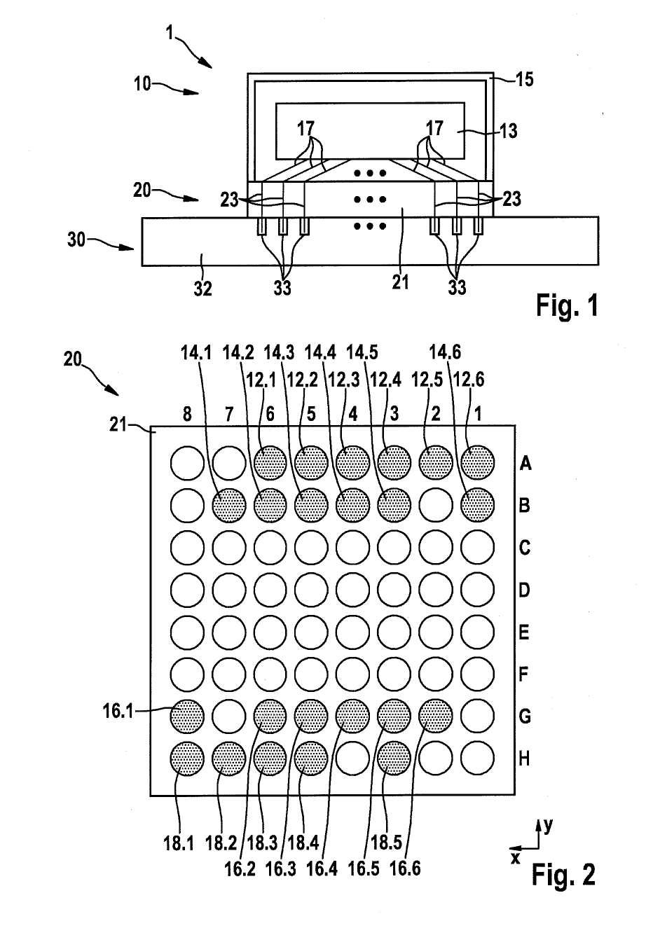

As can be seen from FIGS. 1 through 4, the depicted exemplary embodiment of a component system 1 according to the present invention includes a direction-dependent electrical and/or electronic component 10, for example a rotational rate sensor or an acceleration sensor, including a predetermined first number of functions to be contacted 12.1 through 18.5, and a component bearer 30 that has a predetermined layout having a predetermined second number of second contact elements 33. Direction-dependent electrical and/or electronic component 10 includes a contacting device 20 having a basic body 21 and a plurality of first contact elements 23 that, according to a predetermined connection assignment, are each assigned to a function to be contacted 12.1 through 18.5 and are situated on basic body 21 with a predetermined positioning.

According to the present invention, the positioning of first contact elements 23 on basic body 21 is made rotationally symmetrical about an angle of 90°, so that given a rotation by 90° of direction-dependent electrical and/or electronic component 10, no different component-based functions 12.1 through 18.5 lie against one another.

As can also be seen from FIG. 1, the depicted direction-dependent electrical and/or electronic component 10 includes a sensor element 13, situated inside a housing 15, having a predetermined number of functions to be contacted 12.1 through 18.5, which are connected via corresponding electrical connections 17 to individual first contact elements 23, which in the depicted exemplary embodiment are realized as connecting pins, the number of first contact elements 23 corresponding to the number of functions to be contacted 12.1 through 18.5. In the depicted exemplary embodiment, basic body 32 is rectangular and is realized as a part of housing 15 and terminates it downwardly. In the depicted exemplary embodiment, component bearer 30 is realized as a circuit board having a basic body 32 in which second contact elements 33 are made as pin receptacles. In alternative specific embodiments (not shown), contacting device 20 can be realized as a component base into which component 10 is plugged. In this way, the connection assignment, or assignment of first contact elements 23 to the functions to be contacted 12.1 through 18.5 of component 10, can advantageously be adapted in such a way that the corresponding direction-dependent electrical and/or electronic component 10 can be assembled on component bearer 30 both in a 0° orientation and in a 90° orientation. In this way, it is advantageously possible to correspondingly adapt conventional sensor types known from the existing art in order to achieve the rotational symmetry.

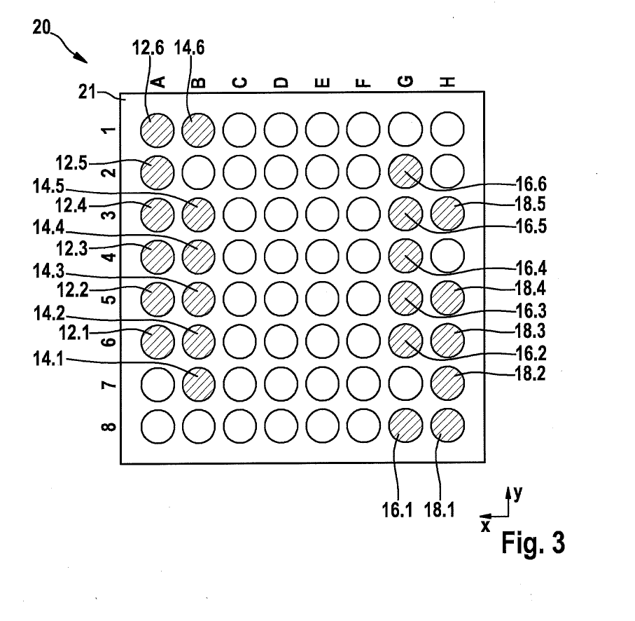

As can be further seen from FIGS. 2 and 3, for the simplification of the representation and of the description, contacting device 20 is rectangular and is shown having a predetermined 8×8 raster having rows A through H and having columns 1 through 8. Here, first contact elements 23, assigned to functions to be contacted 12.1 through 18.5, are shown as filled given assembly in a first detection of direction X, and are shown as hatched given assembly in a second direction of detection Y. FIGS. 2 and 3 each show contacting device 20 according to the present invention of direction-dependent electrical and/or electronic component 10. In FIG. 2, contacting device 20 is oriented in the first direction of detection X (transverse direction), i.e. the corresponding direction-dependent electrical and/or electronic component 10 is oriented in such a way that an associated physical quantity is acquired in the indicated first direction of detection X. In FIG. 3, contacting device 20 is rotated by an angle of 90°, and is oriented in the second direction of detection Y (vertical direction), i.e. the corresponding direction-dependent electrical and/or electronic component 10 is oriented in such a way that an associated physical quantity is acquired in the indicated second direction of detection X.

As can be further seen from FIGS. 2 and 3, functions that are to be contacted 12.1 through 12.6 are assigned to first contact elements 23 at raster positions A1 through A6, a function to be contacted 12.1 being assigned to a first contact element 23 at raster position A6, a function 12.2 being assigned to a first contact element 23 at raster position A5, etc. Functions to be contacted 14.1 through 14.6 are assigned to first contact elements 23 at raster positions B1 and B2 through B7, a function to be contacted 14.1 being assigned to a first contact element 23 at raster position B7, a function 14.2 being assigned to a first contact element 23 at raster position B6, etc. Functions to be contacted 16.1 through 16.6 are assigned to first contact elements 23 at raster positions G2 through G6 and G8, a function to be contacted 16.1 being assigned to a first contact element 23 at raster position G8, a function 16.2 being assigned to a first contact element 23 at raster position G6, etc. Functions to be contacted 18.1 through 18.5 are assigned to first contact elements 23 at raster positions H3 and H5 through H8, a function to be contacted 18.1 being assigned to a first contact element 23 at raster position H8, a function 18.2 being assigned to a first contact element 23 at raster position H7, etc.

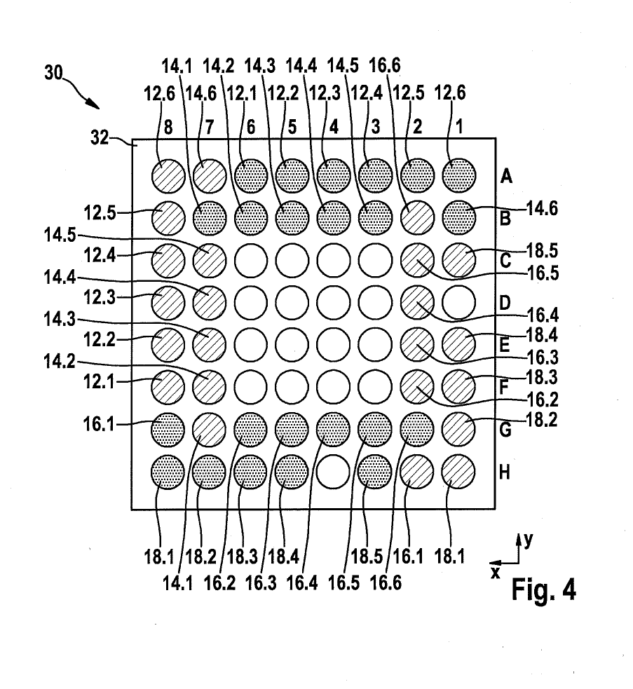

As can also be seen from FIG. 4, for the simplification of the representation and of the description component bearer 30 is rectangular, analogous to contacting device 20, and is shown having a predetermined 8×8 raster having rows A through H and columns 1 through 8. Here the number of second contact elements 33 is selected twice as great as the number of first contact elements 23, and in each case a first contact element 23 of contacting device 20 is capable of being connected to two second contact elements 33 of component bearer 30. In the depicted exemplary embodiment, second contact elements 33 of component bearer 30 are shown as filled in, the bearer being connected to functions to be contacted 12.1 through 18.5 via corresponding first contact elements 23 in the case of assembly to direction-dependent electrical and/or electronic component 10 where said component is oriented in first direction of detection X. Second contact elements 33 of component bearer 30 are shown as hatched, the bearer being connected to functions to be contacted 12.1 through 18.5 via corresponding first contact elements 23 in the case of assembly to direction-dependent electrical and/or electronic component 10 where said component is oriented in second direction of detection Y.

As can also be seen from FIG. 4, due to the positioning, rotationally symmetrical about an angle of 90°, of first contact elements 23 on basic body 21, given a rotation of direction-dependent electrical and/or electronic component 10 by 90° no different component-based functions 12.1 through 18.5 lie against one another, because none of the second contact elements 33 is capable of being connected to two different functions to be contacted 12.1 through 18.5. This means that second contact elements 33, used in the case of assembly in first direction of detection X, remain free given an assembly in second direction of detection Y, and vice versa. In order to enable error-free operation of direction-dependent electrical and/or electronic component 10 independent of the direction of detection, second contact elements 33 of component bearer 30, which can be connected to the same functions to be contacted 12.1 through 18.5, are electrically connected to one another.

Here, an exception is formed by second contact elements 33 of component bearer 30, which can be used for the automatic determination of the orientation of the assembled direction-dependent electrical and/or electronic component 10. For this purpose, a first contact element 23 of direction-dependent electrical and/or electronic component 10, situated on contacting device 20 at raster position H8, is used as orientation element 18.1. In addition, second contact element 33, situated on component bearer 30 at raster position H1, is connected to a ground potential, and second contact element 33, situated on component bearer 30 at raster position H8, is connected to a supply voltage potential. If, now, direction-dependent electrical and/or electronic component 10 is assembled in first direction of detection X, then the corresponding first connection element 23 situated at raster position H8 of contacting device 20 is connected to second contact element 33, situated at raster position H8 of component bearer 30, and is thus connected to ground potential. If direction-dependent electrical and/or electronic component 10 is assembled rotated by 90°, then the corresponding first connecting element 23, situated at raster position H8 of contacting device 20, is connected to second contact element 33, situated at raster position H1 of component bearer 30, and thus is connected to the supply voltage potential. Through the different voltage potentials, which are a function of the position of installation of the direction-dependent electrical and/or electronic component, the direction-dependent electrical and/or electronic component 10 can either itself recognize the direction of detection in which it has been installed, or the information can be transferred via a further connecting element to an evaluation and control unit that correspondingly processes the information.

Alternatively, the orientation of direction-dependent electrical and/or electronic component 10 can take place by an automatic optical inspection via an imprint made on direction-dependent electrical and/or electronic component 10.

Specific embodiments of the present invention advantageously increase, through the connection assignment rotationally symmetrical about an angle of 90°, the flexibility and the degrees of freedom for direction-dependent components. In this way, standard layouts can be created that can be used by a maximum number of clients having different demands without having to keep available too many assembly positions on the circuit board.

1.-10. (canceled)

11. A device for contacting a direction-dependent component that is at least one of electrical and electronic and that includes a predetermined first number of functions to be contacted, comprising:
a basic body; and
a predetermined first number of first contact elements, each assigned, according to a predetermined connection assignment, to a function to be contacted, and the first contact elements situated with a predetermined positioning on the basic body, wherein the positioning of the first contact elements on the basic body is made rotationally symmetrical about an angle of 90°, so that when there is a rotation of the direction-dependent component by 90°, no different component-based functions lie against one another.

12. The device as recited in claim 11, wherein the basic body is realized one of as a part of a component housing and as a component base.

13. The device as recited in claim 11, wherein the basic body is one of circular and rectangular.

14. The device as recited in claim 11, wherein the number of first contact elements corresponds to the first number of functions to be contacted.

15. A component system, comprising:
a direction-dependent component that is at least one of electrical and electronic and that includes a predetermined first number of functions to be contacted; and
a component bearer that has a predetermined layout having a predetermined second number of second contact elements, the direction-dependent component including a contacting device having a basic body and having a plurality of first contact elements that are each assigned, according to a predetermined connection assignment, to a function to be contacted, and that are situated on the basic body with a predetermined positioning, wherein the positioning of the first contact elements on the basic body is made rotationally symmetrical about an angle of 90°, so that when there is a rotation of the direction-dependent component by 90°, no different component-based functions lie against one another.

16. The component system as recited in claim 15, wherein the second number of second contact elements is selected at least twice as large as the first number of first contact elements, each first contact element being capable of being connected to two second contact elements.

17. The component system as recited in claim 16, wherein the first contact elements are realized as connecting pins and the second contact elements are realized as pin receptacles.

18. The component system as recited in claim 15, wherein the second contact elements are situated on the component bearer in such a way that the direction-dependent component is capable of being contacted, in one of a first position having a first direction of detection and in a second position having a second direction of detection, to the component bearer, the second direction of detection having an angle of 90° to the first direction of detection.

19. The component system as recited in claim 18, wherein a first contact element of the direction-dependent component is realized as an orientation element that, in the first position, is contacted to a second contact element that is connected to a first electrical potential, and in the second position is connected to another second contact element that is connected to a second electrical potential, it being possible, by querying the electrical potential present at the orientation element, to determine a current orientation of the direction-dependent component and thus a current direction of detection.

20. The component system as recited in claim 15, wherein the direction-dependent component includes at least one of an acceleration sensor and a rotational rate sensor, and the component bearer includes a circuit board.
